(19) United States
(12) Patent Application Publication
(10) Pub. No.: US 2014/0174361 A1
(43) Pub. Date: Jun. 26, 2014

(54) HEATED BACKING PLATE

(71) Applicant: Applied Materials, Inc., Santa Clara, CA (US)

(72) Inventors: Jrjyan Jerry CHEN, Campbell, CA (US); Soo Young CHOI, Fremont, CA (US); Young Jin CHOI, Santa Clara, CA (US); Yi CUI, San Jose, CA (US); Beom Soo PARK, San Jose, CA (US); Robin L. TINER, Santa Cruz, CA (US)

(73) Assignee: APPLIED MATERIALS, INC., Santa Clara, CA (US)

(21) Appl. No.: 14/061,831

(22) Filed: Oct. 24, 2013

Related U.S. Application Data
(60) Provisional application No. 61/740,912, filed on Dec. 21, 2012.

(51) Int. Cl. C23C 16/44

(52) U.S. Cl. CPC C23C 16/4401
USPC 118/723 R

(57) ABSTRACT

The present invention generally relates to a heated backing plate coupled to a gas distribution showerhead in a PECVD chamber. The backing plate is heated by circulating a heating fluid either through channels formed within the backing plate or a tube coupled to the backing plate. A heated backing plate heats up the gas distribution showerhead, which improves the cleaning rate of the PECVD chamber that performs low temperature processes.

### CROSS-REFERENCE TO RELATED APPLICATIONS

This application claims benefit of U.S. Provisional Patent Application Ser. No. 61/740,912 (APPM/20245L), filed Dec. 21, 2012, which is herein incorporated by reference.

### BACKGROUND OF THE INVENTION

1. Field of the Invention

Embodiments of the present invention generally relate to a plasma enhanced chemical vapor deposition (PECVD) chamber and cleaning methods.

2. Description of the Related Art

PECVD is generally employed to deposit thin films on substrates, such as organic light emitting diode (OLED) substrates and semiconductor substrates. PECVD is generally accomplished by introducing a precursor gas into a vacuum chamber having a substrate disposed on a substrate support. The precursor gas is typically directed through a gas distribution showerhead situated near the top of the vacuum chamber. The precursor gas in the vacuum chamber is excited into a plasma by applying an RF power to a chamber electrode from one or more RF sources coupled to the chamber. The plasma forms a layer of material on a surface of a substrate that is positioned on a substrate support. The gas distribution showerhead is generally connected to an RF power source and the substrate support is typically connected to the chamber body to create an RF power return path.

The process temperature of PECVD processes varies depending on the types of processes. Some processes, such as thin film encapsulation (TFE), require a low temperature. During a TFE process, the temperature of the substrate support is typically maintained at around 80 degrees Celsius. Other thin film depositions using PECVD may maintain the temperature of the substrate support at over 200 degrees Celsius. A PECVD chamber may have residue from the deposition process collecting on the walls and other surfaces, thus a routine cleaning is needed. A low temperature negatively affects the cleaning rate, thus an improved apparatus and cleaning method are needed to enhance the cleaning rate of PECVD chambers performing low temperature processes.

### SUMMARY OF THE INVENTION

The present invention generally relates to a heated backing plate coupled to a gas distribution showerhead in a PECVD chamber. The backing plate is heated by circulating a heating fluid either through channels formed within the backing plate or a tube coupled to the backing plate. A heated backing plate heats up the gas distribution showerhead, which improves the cleaning rate of the PECVD chamber that performs low temperature processes.

In one embodiment, a PECVD chamber is disclosed. The PECVD chamber comprises a gas distribution showerhead and a backing plate coupled to the gas distribution showerhead. The backing plate has a first surface facing the gas distribution showerhead and a second, substantially planar surface opposite the first surface. The PECVD chamber also comprises at least one tube disposed over at least a portion of the second surface of the backing plate and one or more clamps that couple the at least one tube to the second surface of the backing plate.

In another embodiment, a PECVD chamber is disclosed. The PECVD chamber comprises a gas distribution showerhead and a backing plate coupled to the gas distribution showerhead. The backing plate has a plurality of channels formed therein, and a plurality of tubes connect the ends of the plurality of channels.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PECVD apparatus according to one embodiment of the invention.

FIG. 2 is a top view of a backing plate according to one embodiment of the invention.

FIG. 3 is a cross sectional view of a PECVD apparatus according to another embodiment of the invention.

FIG. 4 is an isometric view of a backing plate according to one embodiment of the invention.

FIG. 5 is a top view of a backing plate according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally relates to a heated backing plate coupled to a gas distribution showerhead in a PECVD chamber. The backing plate is heated by circulating a heating fluid either through channels formed within the backing plate or a tube coupled to the backing plate. A heated backing plate heats up the gas distribution showerhead, which improves the cleaning rate of the PECVD chamber that performs low temperature processes.

The description herein will be made with reference to a PECVD chamber available from AKT America, Inc., a subsidiary of Applied Materials, Inc., Santa Clara, Calif. It is to be understood that the embodiments herein are equally applicable to other processing chambers as well, including processing chambers sold by other manufacturers.

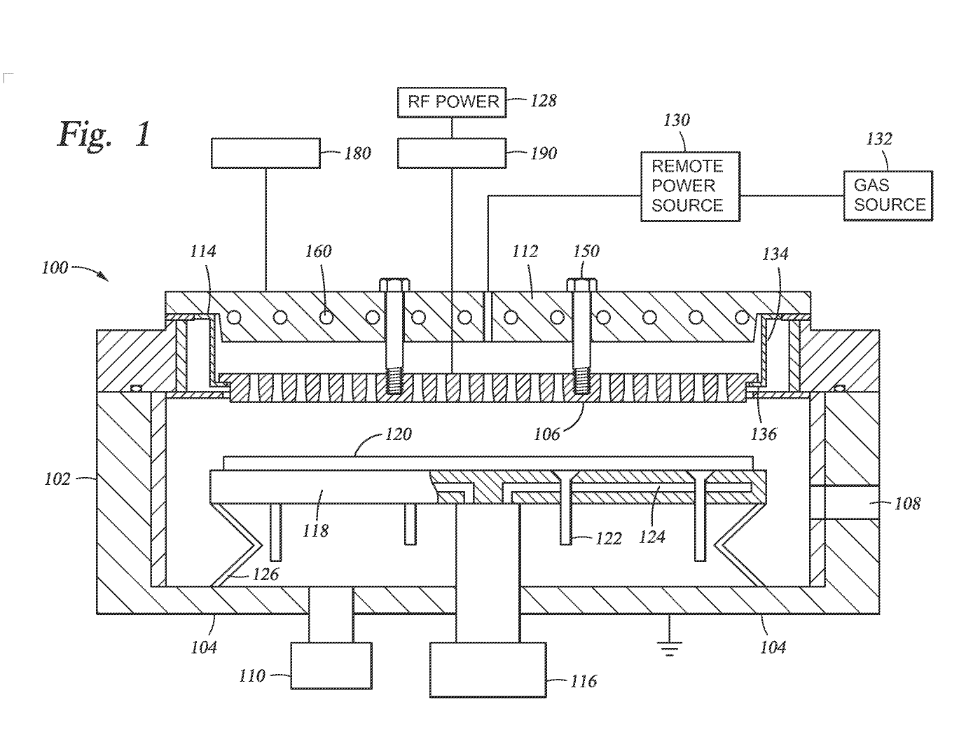

FIG. 1 is a cross sectional view of a PECVD apparatus that may utilize the heated backing plate described herein. The apparatus includes a chamber 100 in which one or more films may be deposited onto a substrate 120. The chamber 100 generally includes walls 102, a bottom 104 and a gas distribution showerhead 106 which define a process volume. A substrate support 118 is disposed within the process volume. The process volume is accessed through a slit valve opening 108 such that the substrate 120 may be transferred in and out of the chamber 100. The substrate support 118 may be coupled to an actuator 116 to raise and lower the substrate support 118. Lift pins 122 are moveably disposed through the substrate support 118 to move a substrate to and from the substrate receiving surface. The substrate support 118 may also include heating and/or cooling elements 124 to maintain the substrate support 118 at a desired temperature. For a TFE process, the temperature of the substrate support 118 is typically maintained at 80 degrees Celsius. The substrate support 118 may also include RF return straps 126 to provide an RF return path at the periphery of the substrate support 118.

The gas distribution showerhead 106 is coupled to a backing plate 112 by a fastening mechanism 150. The gas distribution showerhead 106 may be coupled to the backing plate 112 by one or more fastening mechanisms 150 to help prevent sag and/or control the straightness/curvature of the gas distribution showerhead 106. The backing plate 112 may include conduits for flowing a heating fluid therein. In one embodiment, the backing plate 112 has a plurality of channels 160 formed therein. Typically these channels 160 are gun drilled and may be in any pattern that provides a good coverage of the backing plate 112. In one embodiment, the channels 160 are parallel to each other. The ends of the channels are connected by a plurality of tubes to form a continuous path. A heat exchanger 180 is coupled to the channels 160 to control the temperature of the heating fluid.

A gas source 132 is coupled to the backing plate 112 to provide gas through gas passages in the gas distribution showerhead 106 to a processing area between the gas distribution showerhead 106 and the substrate 120. A vacuum pump 110 is coupled to the chamber 100 to control the process volume at a desired pressure. An RF source 128 is coupled through a match network 190 to the backing plate 112 and/or to the gas distribution showerhead 106 to provide an RF current to the gas distribution showerhead 106. The RF current creates an electric field between the gas distribution showerhead 106 and the substrate support 118 so that a plasma may be generated from the gases between the gas distribution showerhead 106 and the substrate support 118.

A remote plasma source 130, such as an inductively coupled remote plasma source, may also be coupled between the gas source 132 and the backing plate 112. Between processing substrates, a cleaning gas may be provided to the remote plasma source 130 so that a remote plasma is generated. The radicals from the remote plasma may be provided to chamber 100 to clean chamber 100 components. The cleaning gas may be further excited by the RF source 128 provided to the gas distribution showerhead 106. During the cleaning process, the backing plate 112 may be heated to a temperature of around 150 degrees Celsius, by circulating the heating fluid through the channels and the tubes.

The gas distribution showerhead 106 may additionally be coupled to the backing plate 112 by showerhead suspension 134. The showerhead suspension 134 provides a thermal transfer contact between the gas distribution showerhead 106 and the backing plate 112. The showerhead suspension 134 may have a lip 136 upon which the gas distribution showerhead 106 may rest. The backing plate 112 may rest on an upper surface of a ledge 114 coupled to the chamber walls 102 to seal the chamber 100. In one embodiment, the showerhead suspension 134 is a flexible metal skirt interconnected between the backing plate 112 and the gas distribution showerhead 106.

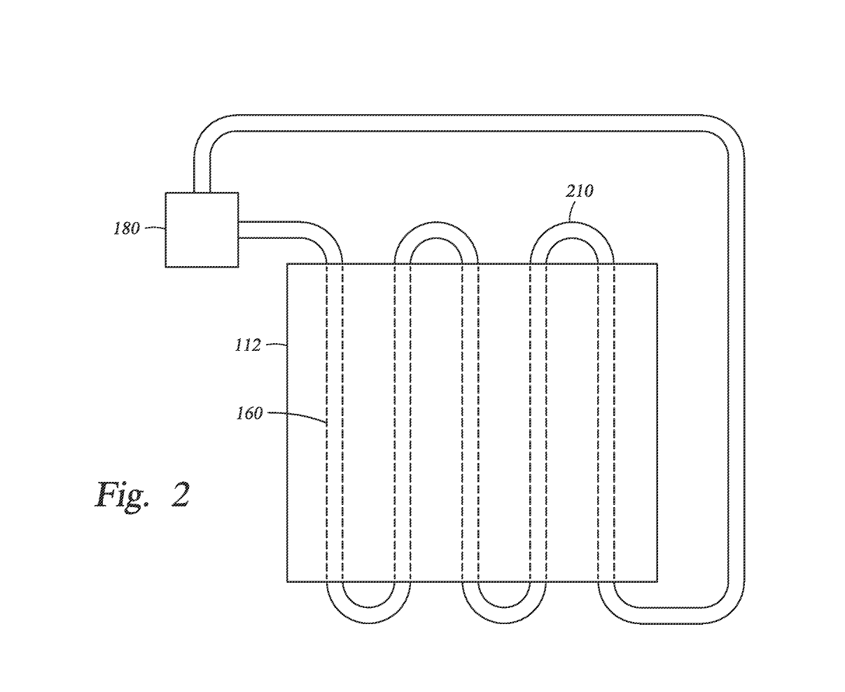

FIG. 2 is a top view of the backing plate 112 described in FIG. 1. The plurality of channels 160 are formed within the backing plate 112. In one embodiment, the channels 160 are formed by gun drilling. The ends of the channels 160 are connected by tubes 210 to form a continuous path. The tubes 210 may be made of an electrically insulating material. In one embodiment, the tubes 210 are made of polytetrafluoroethylene (PTFE). The channels 160 may be formed in any pattern that provides a good coverage of the backing plate 112. In one embodiment, the channels 160 are parallel to each other. The tubes 210 are connected to the heat exchanger 180. During the cleaning process, a heating fluid is heated to a predetermined temperature by the heat exchanger 180 and then circulates through the channels 160 and the tubes 210 to elevate the temperature of the backing plate 112. Any organic heat transfer fluid may be used as the heating fluid. In one embodiment, a Galden® heat transfer fluid is used. The heating fluid may elevate the temperature of the backing plate 112 to around 150 degrees Celsius. The heated backing plate 112 in turn heats up the gas distribution showerhead 106 by conduction and radiation. The thermal transfer contact between the backing plate 112 and the gas distribution showerhead 106, as described above, provides one or more paths for conduction heat transfer. The backing plate 112 and the gas distribution showerhead 106 are in close proximity, thus a heated backing plate 112 may transfer heat to the gas distribution showerhead 106 by radiation. A higher temperature increases the cleaning rate of the PECVD chamber. The cleaning rate, as measured by the etching rate, shows an increase from 5,110 Angstroms per minute without heating the backing plate 112, to 9,238 Angstroms per minute with heating the backing plate 112.

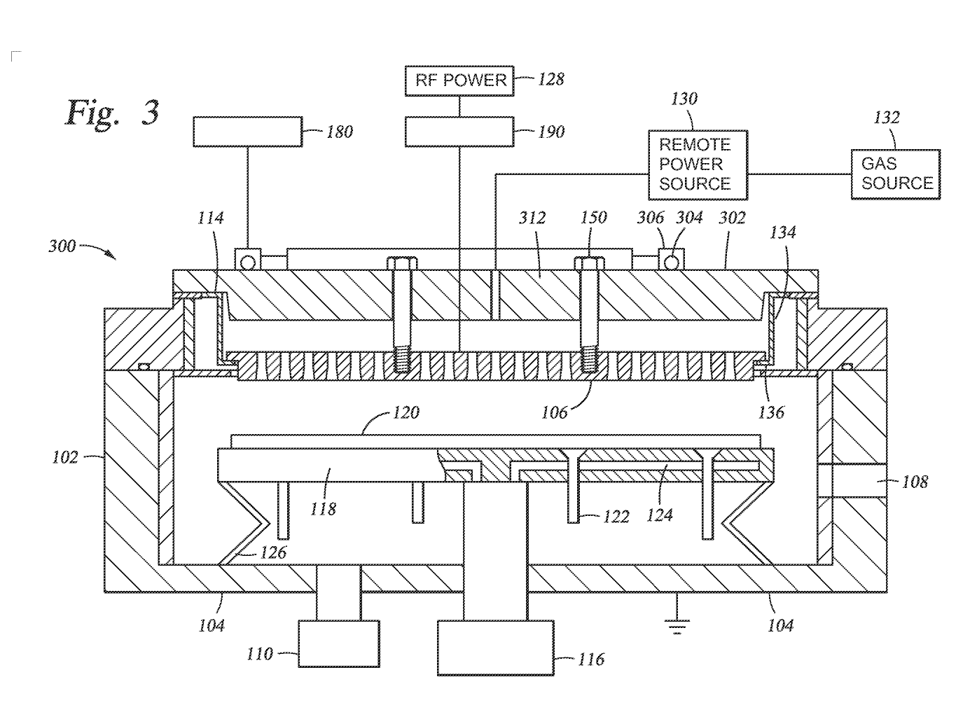

FIG. 3 is a cross sectional view of a PECVD apparatus according to another embodiment of the invention. The apparatus includes a chamber 300 in which one or more films may be deposited onto a substrate 120. The chamber 300 has a backing plate 312 coupled to the gas distribution showerhead 106. The backing plate 312 has a substantially planar top surface 302 that is opposite to the surface where the gas distribution showerhead 106 is coupled thereto. A tube 304 is coupled to the top surface 302 of the backing plate 312 by a plurality of clamps 306. The heat exchanger 180 is coupled to the tube 304. The tube 304 may be made of a metal such as aluminum, stainless steel, or copper, in order to effectively transfer heat to the backing plate 312 from the heating fluid. The plurality of clamps 306 may be made of metal as well. In one embodiment, the backing plate 312 may be a combination of the backing plate 112 in FIG. 1 and the backing plate 312 in FIG. 3. The combination backing plate has both gun drilled channels formed within and the at least one tube coupled to the top surface by the plurality of clamps. During the cleaning process, the heating fluid may be circulating through the channels, the tubes, or both the channels and the tubes.

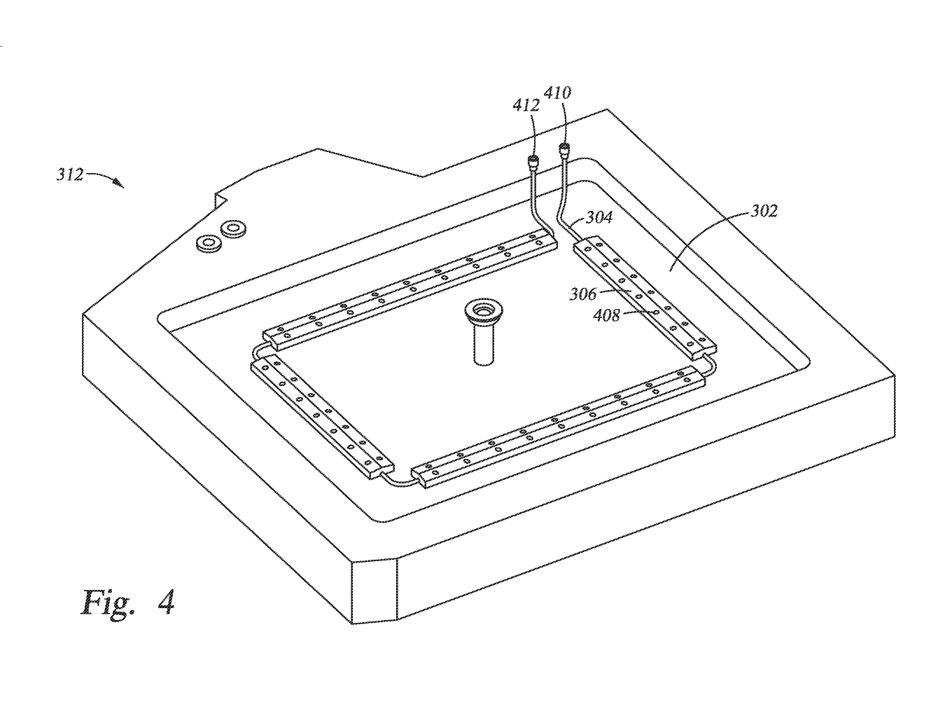

FIG. 4 is an isometric view of the backing plate 312 according to one embodiment of the invention. As shown in FIG. 4, the backing plate 312 has the substantially planar top surface 302 and the tube 304 is coupled to the top surface 302. The tube 304 may form any pattern that provides a good coverage of the backing plate 312. In one embodiment, the tube 304 comprises four straight sections as shown in FIG. 4. Two of the sections are parallel to each other and to two sides of the backing plate 312. The other two sections are parallel to each other and to the other two sides of the backing plate 312. The tube 304 may be a single continuous tube that bends at the corners. Alternatively, the tube 304 may comprise a plurality of tubes. In one embodiment, the tube 304 comprises four straight tubes connected by three elbow shaped connectors at the corners. The tube 304 has an inlet port 410 and an outlet port 412 for a heating fluid to enter into and leave from the tube 304. The heat exchanger 180 in FIG. 3 is coupled to the tube 304 at the inlet port 410 and the outlet port 412.

During the cleaning process, a heating fluid, such as Galden® heat transfer fluid, enters the tube 304 through the inlet port 410. The heating fluid has already been heated to a predetermined temperature by the heat exchanger 180. As the heating fluid flows through the tube 304, the backing plate 312 is heated by convection, conduction and radiation heating. The flow of the heating fluid creates a convection current that heats up the backing plate 312. The tube 304 and the plurality of clamps 306 may be made of a metal, which is a conductor of heat. Thus, heat from the heating fluid is transferred to the backing plate 312 by conduction. Lastly, since the tube 304 is in close proximity with the backing plate 312, heat from the heating fluid flowing through the tube 304 may be transferred to the backing plate 312 by radiation. In one embodiment, the backing plate 312 is heated to a temperature of around 150 degrees Celsius. The heating fluid, after transferring heat to the backing plate 312, flows out of the tube 304 through the outlet port 412, and gets heated again by the heat exchanger 180 to the predetermined temperature.

The tube 304 is coupled to the top surface 302 by the plurality of clamps 306. The plurality of clamps 306 may include four clamps, one for each straight section of the tube 304. Alternatively, there may be several discrete clamps for each straight section of the tube 304. Any tubing clamps may be used to couple the tube 304 to the top surface 302 of the backing plate 312. As shown in FIG. 4, four clamps 306 are used to couple the tube 304 to the top surface 302. Each clamp 306 covers a substantial portion of one of the straight sections of the tube 304, leaving the corners uncovered. The clamps 306 may be secured to the top surface 302 with bolts, screws, or any other fastening devices known in the art. In one embodiment, screws are used. As shown in FIG. 4, a plurality of screws 408 are used to secure the clamp 306 to the top surface 302. The screws 408 are disposed in pairs and spaced apart along the length of the clamp 306, and the tube 304 is disposed between each pair of the screws 408. In one embodiment, nine pairs of screws are used on each of the long sides of the clamps and seven pairs are used on each of the short sides of the clamps.

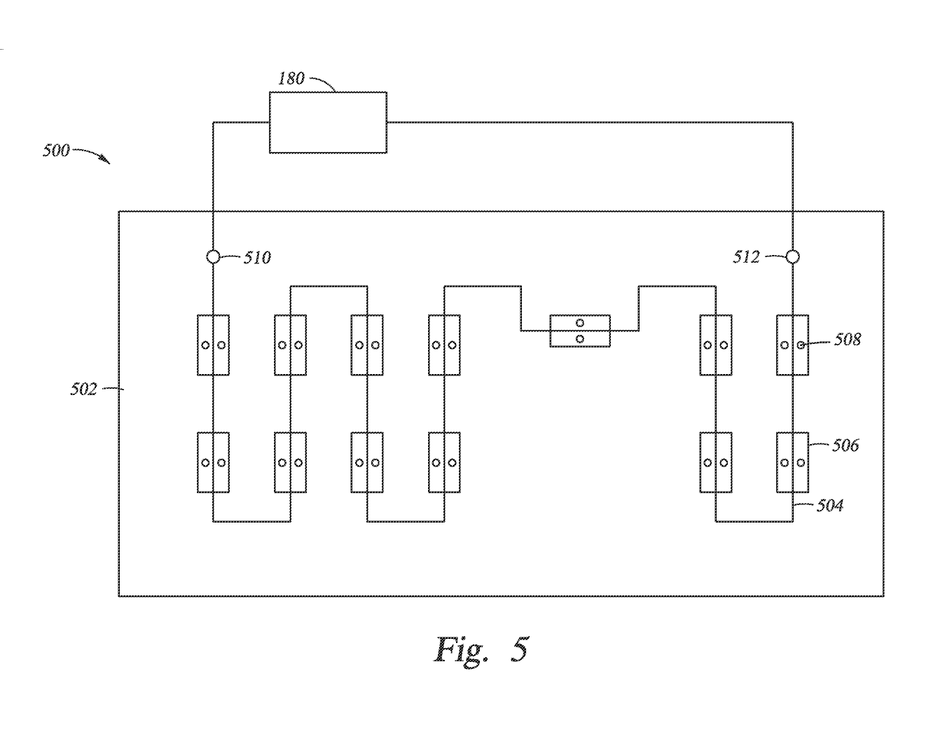

FIG. 5 is a top view of a backing plate 500 according to another embodiment of the invention. A backing plate 500 has a substantially planar top surface 502 and a tube 504 is coupled to the top surface 502. The tube 504 may form any pattern that provides a good coverage of the backing plate. In one embodiment, the tube 504 comprises a plurality of sections and forms a serpentine/tortuous pattern, as shown in FIG. 5. The tube 504 may be a single continuous tube that bends at the corners. Alternatively, the tube 504 may comprise a plurality of straight tubes connected by elbow shaped connectors at the corners. The tube 504 has an inlet port 510 and an outlet port 512 for a heating fluid to enter into and leave from the tube 504. The heat exchanger 180 is coupled to the tube 504 at the inlet port 510 and the outlet port 512.

During the cleaning process, a heating fluid, such as Galden® heat transfer fluid, enters the tube 504 through the inlet port 510. The heating fluid has already been heated to a predetermined temperature by the heat exchanger 180. As the heating fluid flows through the tube 504, the backing plate 500 is heated by convection, conduction and radiation heating. The flow of the heating fluid creates a convection current that heats up the backing plate 500. The tube 504 and a plurality of clamps 506 may be made of a metal, which is a conductor of heat. Thus, heat from the heating fluid is transferred to the backing plate 500 by conduction. Lastly, since the tube 504 is in close proximity with the backing plate 500, heat from the heating fluid flowing through the tube 504 may be transferred to the backing plate 500 by radiation. In one embodiment, the backing plate 500 is heated to a temperature of around 150 degrees Celsius. The heating fluid, after transferring heat to the backing plate 500, flows out of the tube 504 through the outlet port 512, and gets heated again by the heat exchanger 180 to the predetermined temperature.

The tube 504 is coupled to the top surface 502 by the plurality of clamps 506. Any tubing clamps may be used to couple the tube 504 to the top surface 502 of the backing plate 500. As shown in FIG. 5, one or more clamps 506 are used to couple the straight sections of the tube 504, depending on the length of the straight section of the tube 504. For a longer straight section, two clamps, or one long clamp may be used. For a shorter straight section, one or none of the clamps is used. The clamps 506 may be secured to the top surface 502 with bolts, screws, or any other fastening devices known in the art. In one embodiment, screws 508 are used. As shown in FIG. 5, a plurality of screws 508 are used to secure the clamps 506 to the top surface 502. The screws 508 are disposed in pairs and spaced apart along the length of the clamp 506, and the tube 504 is disposed between each pair of the screws 508.

In summary, a heated backing plate is utilized to elevate the temperature of the gas distribution showerhead. As the result, the cleaning rate of a PECVD that performs low temperature processes such as TFE is improved. The backing plate may be heated with a heating fluid circulating through channels formed within the backing plate. The backing plate may also be heated with a heating fluid circulating through a tube coupled to the backing plate.

While the foregoing is directed to embodiments of the present invention, other and further embodiments of the invention may be devised without departing from the basic scope thereof, and the scope thereof is determined by the claims that follow.

1. A plasma enhanced chemical vapor deposition chamber, comprising:
a gas distribution showerhead;
a backing plate coupled to the gas distribution showerhead, the backing plate having a first surface facing the gas distribution showerhead and a second, substantially planar surface opposite the first surface;
at least one tube disposed over at least a portion of the second surface of the backing plate; and
one or more clamps coupling the at least one tube to the second surface of the backing plate.

2. The chamber of claim 1, further comprising a heat exchanger coupled to the at least one tube.

3. The chamber of claim 2, further comprising a thermal transfer contact between the gas distribution showerhead and the backing plate.

4. The chamber of claim 3, wherein the thermal transfer contact comprises a showerhead suspension connecting the backing plate and the gas distribution showerhead.

5. The chamber of claim 3, wherein the thermal transfer contact comprises a sheet metal skirt interconnected between the backing plate and the gas distribution showerhead.

6. The chamber of claim 3, wherein the at least one tube comprises four sections wherein two sections are parallel to each other and to two sides of the backing plate and the other two sections are parallel to each other and to the other two sides of the backing plate.

7. The chamber of claim 3, wherein the at least one tube forms a tortuous path.

8. The chamber of claim 1, wherein the at least one tube comprises aluminum, stainless steel, or copper.

9. A plasma enhanced chemical vapor deposition chamber, comprising:
a gas distribution showerhead;
a backing plate coupled to the gas distribution showerhead, the backing plate having a plurality of channels formed therein; and
a plurality of tubes connecting the ends of the plurality of channels.

10. The chamber of claim 9, further comprising a heat exchanger coupled to the plurality of tubes.

11. The chamber of claim 10, wherein the plurality of channels are parallel to each other.

12. The chamber of claim 11, further comprising a thermal transfer contact between the gas distribution showerhead and the backing plate.

13. The chamber of claim 12, wherein the thermal transfer contact comprises a showerhead suspension connecting the backing plate and gas distribution showerhead.

14. The chamber of claim 12, wherein the thermal transfer contact comprises a sheet metal skirt interconnected between the backing plate and the gas distribution showerhead.

15. The chamber of claim 9, wherein the plurality of tubes comprises an electrically insulating material.

16. The chamber of claim 15, wherein the plurality of tubes comprises PTFE.
